(19) United States
(12) Patent Application Publication
(10) Pub. No.: US 2025/0308767 A1
(43) Pub. Date: Oct. 2, 2025

(54) VARIABLE INDUCTOR AND CONTROL SYSTEM FOR THE VARIABLE INDUCTOR

(71) Applicant: The Alfred E. Mann Foundation for Scientific Research, Valencia, CA (US)

(72) Inventor: Leslie Farkas, Ventura, CA (US)

(21) Appl. No.: 19/091,743

(22) Filed: Mar. 26, 2025

Related U.S. Application Data
(60) Provisional application No. 63/572,104, filed on Mar. 29, 2024.

(51) Int. Cl. H01F 29/00

(52) U.S. Cl. CPC H01F 29/00

(57) ABSTRACT

A control system includes a variable inductor including a magnetic core, a first coil wound around the magnetic core, and a control coil wound around the magnetic core; and a sensor coil wound around the magnetic core, wherein the first coil wound around the magnetic core is coupled between first and second terminals and has a variable inductance across the first and second terminals.

### CROSS-REFERENCE TO RELATED APPLICATION

This application claims priority to, and the benefit of, U.S. Provisional Patent Application No. 63/572,104, filed on Mar. 29, 2024, the entire content of which is hereby incorporated by reference.

### BACKGROUND

Wireless power transfer devices can be used to inductively transfer power from a primary coil of the wireless power transfer device to a secondary coil of a target device. A power management unit of the target device can then store or use the received power within the target device. This technique can be used, for example, to charge or power implantable medical devices that are implanted subcutaneously below a patient's skin. It can be advantageous for the resonant frequency of the wireless power transfer device to be similar to the resonant frequency of the target device so that the efficiency of the power transfer is improved. However, the resonant frequencies of the wireless power transfer device and of the target device can change for various reasons, such as in response to the presence of parasitic capacitances and parasitic conductance. Parasitic variations can be introduced, for example, by the presence of tissue near the coils or when a conductive surface distorts the magnetic field generated by the primary coil. These parasitic variations can reduce the efficiency of the power transfer.

It can therefore be desirable to couple a variable inductor to the wireless power transfer device in a manner that allows the inductance of the primary coil (and thus the resonant frequency of the wireless power transfer device) to be adjusted by changing the inductance of the variable inductor. Some variable inductors described herein can use a magnetic core having desirable material properties that can become permanently degraded when the permeability of the magnetic core drops below a certain level-a phenomenon called “whapping”. The permeability of a magnetic core can be affected by various influences, such as DC magnetic flux, AC magnetic flux, temperature, and physical shock. These various influences can combine in complex and unpredictable ways within the magnetic core. Thus, it can also be advantageous to monitor the magnetic core's permeability so that the permeability can be prevented from dropping below the level at which whapping occurs.

This background section is provided only for purposes of introducing certain background material relating to the present disclosure and, thus, is not an admission of prior art.

### SUMMARY

According to an aspect, the technology relates to a control system, including a variable inductor including a magnetic core, a first coil wound around the magnetic core, and a control coil wound around the magnetic core; and a sensor coil wound around the magnetic core, wherein the first coil wound around the magnetic core is coupled between first and second terminals and has a variable inductance across the first and second terminals.

In some examples, the control system includes an oscillator coupled to the sensor coil; and a controller coupled to the oscillator and configured to determine, based on an oscillation frequency of the oscillator, an inductance of the variable inductor.

In some examples, the control system includes an electronic system coupled to the first and second terminals of the variable inductor, wherein a resonant frequency of the electronic system depends on the inductance of the variable inductor and is either: less than twenty percent of the oscillation frequency of the oscillator; or more than five times higher than the oscillation frequency of the oscillator.

In some examples, the control system includes a current source configured to provide a DC control current to the control coil to control the inductance of the variable inductor.

In some examples, the controller is coupled to the current source and is configured to determine a maximum DC control current corresponding to a set minimum inductance of the variable inductor.

In some examples, the controller is configured to determine a slope equal to a ratio of a change in the inductance of the variable inductor relative to a corresponding change in the DC control current provided to the control coil.

In some examples, the controller is configured to maintain a change in the slope below a set linearity error.

In some examples, the set linearity error is selected from any percentage between 0.0 and ±15.0.

In some examples, the controller is configured to maintain a rate of change in the DC control current provided to the control coil below a set maximum.

In some examples, the controller is configured to maintain the DC control current provided to the control coil below a set maximum DC control current.

In some examples, the sensor coil includes the control coil wound around the magnetic core.

In some examples, the control system includes a current sensor configured to measure a DC current provided to the control coil.

In some examples, the magnetic core is a three legged core including two outer legs and a middle leg between the two outer legs, wherein the control coil is wound around the middle leg, and wherein the first coil includes two sub-coils respectively wound around the two outer legs.

In some examples, the sensor coil is wound around the middle leg of the three legged core.

In some examples, the inductance of the variable inductor is proportional to a permeability of the magnetic core.

In some examples, the magnetic core includes at least one of a ferrite, a perminvar ferrite, a nickel zinc ferrite, Fair-Rite 61 ferrite, or Fair-Rite 67 ferrite.

According to an aspect, the technology relates to a method for controlling an inductance of a variable inductor, the variable inductor including a magnetic core, a first coil, a control coil, and a sensor coil, the first coil, control coil, and sensor coil each being wound around the magnetic core, and the first coil having a variable inductance across first and second terminals, the method including regulating the inductance of the variable inductor via a DC control current provided by a current source coupled to the control coil; and monitoring an oscillation frequency of an oscillator coupled to the sensor coil.

In some examples, the method includes determining the inductance of the variable inductor based on the oscillation frequency of the oscillator.

In some examples, the method includes increasing the DC control current to the control coil by a set amount in a first increase; determining the inductance of the variable inductor due to the first increase; increasing the DC control current to the control coil by the set amount in a second increase; determining the inductance of the variable inductor due to the second increase; and determining a rate of change in the inductance of the variable inductor relative to the change in the DC control current.

In some examples, the method includes repeatedly increasing the DC control current to the control coil if the rate of change in the inductance of the variable inductor relative to the change in the DC control current is less than or equal to a set linearity error; maintaining, or decreasing, the DC control current to the control coil if the rate of change in the inductance of the variable inductor relative to the change in the DC control current is greater than the set linearity error; and setting a maximum control current in the controller based on the last DC control current that corresponds to the rate of change in the inductance of the variable inductor relative to the change in the DC control current that is less than or equal to the set linearity error.

In some examples, the method includes setting a minimum value of the inductance of the variable inductor in the controller based on the value of the inductance of the variable inductor corresponding to the maximum control current. According to an aspect, the technology relates to a control system, including a variable inductor configured to couple to an electronic system and including a magnetic core, and a control coil wrapped around the magnetic core; a current source configured to provide a DC control current to the control coil; and an inductance sensor configured to measure an inductance of the variable inductor, wherein the control system is configured to set an amplitude of the DC control current based on a measured inductance measured by the inductance sensor.

In some examples, an inductance-variable system includes the control system, the control system including a first coil wound around the magnetic core and electrically coupled between two terminals; and an electronic system coupled to the variable inductor via the two terminals and having a resonant frequency dependent on the inductance of the variable inductor, wherein the control system is configured to set the amplitude of the DC control current further based on the resonant frequency of the electronic system.

In some examples, the electronic system includes a wireless power transfer device including primary coil configured to inductively transmit power.

In some examples, the electronic system further includes an implantable medical device including a secondary coil configured to inductively receive power from the primary coil.

In some examples, the magnetic core includes two outer legs and an intermediate leg, and the control coil is wound around the center leg.

In some examples, the inductance sensor includes a resonant circuit including a sensor coil wound around the magnetic core.

In some examples, the control system is configured to measure an oscillation frequency of the resonant circuit and to calculate the inductance of the variable inductor based on the measured oscillation frequency.

In some examples, the sensor coil and the control coil are the same coil.

In some examples, the sensor coil is separate from, and electrically insulated from, the control coil.

In some examples, the control system includes an AC blocking coil electrically coupled between the current source and the sensor coil.

In some examples, the control system is configured to provide the DC control current with a plurality of amplitudes; measure a plurality of inductance values, respectively corresponding to the plurality of amplitudes, of the variable inductor; and determine, based on the inductance values and the amplitudes, at least one of a lower inductance threshold or an upper amplitude threshold.

In some examples, the control system is configured to calculate a plurality of slope values, each of the slope values being based on a ratio of a difference between a pair of the inductance values to a difference between a corresponding pair of amplitudes; calculate a plurality of slope change values, each of the slope change values being based on a pair of the slope values; determine that a first slope change value of the slope change values exceeds a set linearity error; and determine the at least one of the lower inductance threshold or the upper amplitude threshold based on first impedance value and/or a first amplitude, the first impedance value being corresponding to the first slope change value and the first amplitude corresponding to the first impedance value.

In some examples, the control system is configured to set the amplitude of the DC control current based on whether the inductance of the variable inductor is at or below a lower inductance threshold.

In some examples, the control system is configured to set the amplitude of the DC control current within a range less than an upper amplitude threshold.

In some examples, the control system is configured to set the amplitude of the DC control current based on a rate of change of the inductance of the magnetic core, with respect to a corresponding change of the amplitude of the DC control current.

This Summary section introduces some features of nonlimiting and non-exhaustive examples of the present disclosure, and is not intended to limit the scope of the claims.

### BRIEF DESCRIPTION OF THE DRAWINGS

The drawings, together with the specification, illustrate nonlimiting and non-exhaustive examples of the present disclosure.

FIG. 1 depicts a variable inductor with a control coil functioning as a sensor coil according to some examples.

FIG. 2 depicts a block diagram for a control system for a variable inductor according to some examples.

FIG. 3 depicts a variable inductor with a separate sensor coil according to some examples.

FIG. 4 depicts a block diagram for a control system for a variable inductor according to some examples.

FIG. 5 depicts part of a control system for a variable inductor according to some examples.

FIG. 6 depicts part of a control system for a variable inductor according to some examples.

FIG. 7 depicts a flowchart for a method of calibration for a variable inductor according to some examples.

FIG. 8 depicts a flowchart for a method of operating a control system for a variable inductor according to some examples.

### DETAILED DESCRIPTION

Various nonlimiting and non-exhaustive examples of variable inductors, control systems for variable inductors, and methods of operation such control systems will now be described herein with reference to the drawings. The variable inductors may include a magnetic core with a control coil and a sensor coil wound around the magnetic core. The inductance of the magnetic core can be controllably adjusted by controlling the amplitude of a DC current provided to the control coil, and the inductance of the magnetic core can be monitored via the sensor coil. By monitoring the magnetic core's inductance, the control system may operate the variable inductor within a range of inductances in which the inductance varies linearly with respect to the control current amplitude (referred to herein as the “linear range”). As explained herein, when the magnetic core's inductance drops below a threshold level, it enters another range in which the inductance varies non-linearly with respect to the control current amplitude (referred to herein as the “nonlinear range”). The magnetic properties of the magnetic core can become permanently degraded when it is operated within the nonlinear range. Operating the variable inductor in a manner that confines the magnetic core's inductance to within the linear range can protect the magnetic core from such permanent changes.

It will be understood that, although the terms “first”, “second”, “third”, etc., may be used herein to describe various elements, processes, or other features, these elements, processes, or features should not be limited by these terms. These terms are only used to distinguish one element, process, or feature from another element, process, or feature. Thus, a first element, process, or feature discussed herein could be termed a second element, process, or feature, without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The terminology used herein is for the purpose of describing particular examples only and is not intended to be limiting of the present disclosure. As used herein, the singular forms “a”, “an” and “the” are intended to include the plural forms as well, unless the context clearly indicates otherwise. It will be further understood that the terms “comprises,” “comprising,” “includes,” and “including,” specify the presence of stated elements, processes, and/or other features, but do not preclude the presence or addition of one or more other elements, processes, and/or features. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing examples of the present disclosure refers to “one or more examples of the present disclosure.” Also, the term “example” is intended to refer to an example.

It will be understood that when an element is referred to as being “on”, “connected to”, “coupled to”, “attached to”, or “adjacent to” another element, it can be directly on, connected to, coupled to, attached to, or adjacent to the other element, or one or more intervening element(s) may be present. In contrast, when an element is referred to as being “directly on,” “directly connected to”, “directly coupled to”, “directly attached to”, or “immediately adjacent to” another element, there are no intervening elements present. Similar terms and phrases should be understood in a similar manner to encompass both direct and indirect affiliations between two or more elements being discussed. In addition, it will also be understood that when an element is referred to as being “between” two elements, it can be the only element between the elements, or one or more intervening elements may also be present.

As used herein, the phrase “at least part” includes part or all of the stated item, the phrase “at least partly” includes the stated item partly or entirely, and similar phrases should be interpreted in a similar manner.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The term “controller” is used herein to include any combination of hardware, firmware, and software, employed to process data or digital signals. Processing unit hardware may include, for example, application specific integrated circuits (ASICs), general purpose or special purpose central processing units (CPUs), digital signal processors (DSPs), graphics processing units (GPUs), and programmable logic devices such as field programmable gate arrays (FPGAs).

The control system, controller, and/or any other relevant devices or components according to examples of the present disclosure described herein may be implemented utilizing any suitable hardware, firmware (e.g. an application-specific integrated circuit), software, or a combination of software, firmware, and hardware. For example, the various components of the control system may be formed on one integrated circuit (IC) chip or on separate IC chips. Further, the various components of the control system may be implemented on a flexible printed circuit film, a tape carrier package (TCP), a printed circuit board (PCB), or formed on one substrate. Further, the various components of the control system may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the example examples of the present disclosure.

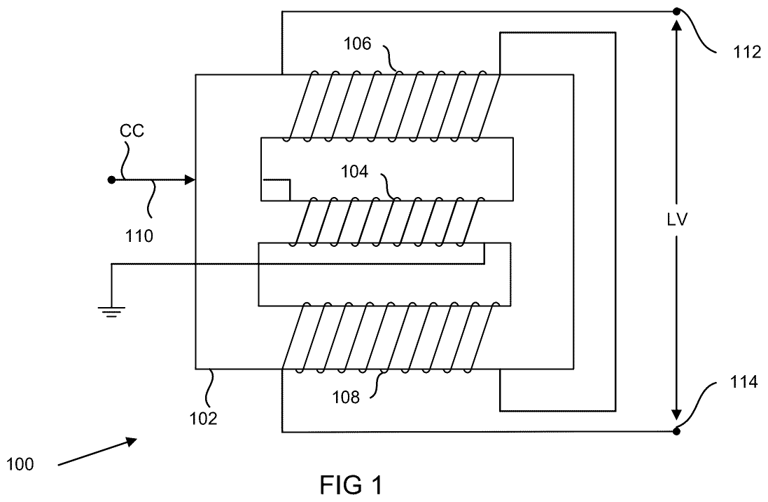

FIG. 1 depicts a variable inductor 100 according to some examples. The variable inductor 100 may include core 102, which is a three-legged core in this example having a center leg and two outer legs. The core 102 may generally form the shape of the number 8. The variable inductor 100 may include a control coil 104 wound around the core 102 (e.g., around the center leg) and two compensation coils 106 and 108 also wound around the core 102 (e.g., around the two outer legs). The two compensation coils 106 and 108 may be electrically coupled together in series or in parallel and may be wound in counter-propagating directions around the two outer legs of the core 102. The two compensation coils 106 and 108 may be electrically coupled between two terminals 112 and 114, which may be connecting points for other circuits or systems to connect to the variable inductor 100. A controllably variable inductance (LV) may be formed between the two terminals 112 and 114.

The inductance of the variable inductor 100 may be controlled via a DC control current (CC) 110 provided to the control coil 104. The core 102 may include a material whose relative permeability decreases as the control current 110 flowing through the control coil 104 increases. For example, the core 102 may include (e.g., be) at least one of a ferrite, a perminvar material, a nickel zinc (NiZn) ferrite, Fair-Rite 61 ferrite, or Fair-Rite 67 ferrite. Thus, the permeability of the core 102 can be controlled by controlling the control current 110. Reference herein to the control current may refer to the absolute value of the control current, because changes to the core's permeability may not depend on the direction in which the control current flows. The two compensation coils 106 and 108 may be inductively coupled to the control coil 104 via the core 102 such that the inductance of the two compensation coils 106 and 108 are also varied based on the magnitude of the control current 110.

The variable inductor 100 may be coupled to another device (e.g., an electronic device) and be used to affect one or more properties of the other device by adjusting the inductance of the variable inductor 100. As an example, the variable inductor 100 may be magnetically coupled to a primary coil of a wireless power transfer device. The wireless power transfer device may be configured to drive the primary coil with an AC current to inductively transfer power from the primary coil to a secondary coil in a target device. The target device may be, for example, a medical device, such as an implantable medical device (e.g., an implantable neurostimulator, an implantable sensor configured to measure electromyography (EMG) signals and to function as part of a prosthetic device (e.g., an artificial limb).

The primary coil, secondary coil, and variable inductor 100 may form an inductive coupling system, and it can be desirable for the resonant frequency of this inductive coupling system to be close to, or equal to, the operating frequency of the primary coil (the frequency of the AC current used to drive the primary coil). This can improve the efficiency of power transfer from the primary coil to the secondary coil. However, the resonant frequency of the inductive coupling system can be altered by influences such as parasitic capacitances and parasitic conductance, which may arise in the presence of biological tissue or conductive components that may distort the magnetic field generated by the primary coil. The resonant frequency can also change over time as the material properties and structures of the wireless power transfer system and target device degrade over time or are damaged. Because the inductance LV of the variable inductor 100 can influence the resonant frequency of the inductive coupling system, it can be controllably adjusted over time (via the control current 110) to correct these changes in the resonant frequency of the inductive coupling system.

The control coil 104 may be electrically connected to a DC current source and, in this example, may also function as a sensor coil. The inductance LV of variable inductor 100 and the permeability of the material of the core 102 can be controllably adjusted by controlling the amplitude of the control current 110.

As explained above, it can be desirable to operate the variable inductor 100 such that the relative permeability of the core 102 does not drop too low. The permeability of the core 102 is proportional to the inductance of the variable inductor 100. As the control current 110 is increased, the inductance of the variable inductor 100 decreases, the core 102 becomes more magnetized, and the permeability of the core 102 decreases. The permeability of the core 102 can be affected by various other influences as well. For example, the core's permeability may be affected by DC magnetic flux, AC magnetic flux, temperature, and physical shock, and these influences can combine to affect the permeability of the core 102 in complex and unpredictable ways. If the permeability decreases below a certain value, the material properties (e.g., magnetic properties) of the core 102 may experience whapping and be permanently degraded. Such degradation can negatively interfere with subsequent operation of the variable inductor 100.

In some examples, a current source, not shown in FIG. 1, may be configured to provide the DC control current 110 below a set maximum to cause the inductance of the variable inductor 100 and the permeability of the magnetic core 102 to be within a set range of values, for example, values considered to be safe and to be unlikely to cause the permanent changes to the core discussed above.

The maximum DC control current may be determined during a calibration process, empirically, by simulations, and/or based on theoretical models, etc. For example, the maximum DC control current 110 may be determined to consider, and to correct, shifts in the inductance of the variable inductor 100 due to environmental factors, such as changes in operating temperature, proximity to magnetic fields, proximity to large metallic objects, etc.

In some other examples, over magnetization of the variable inductor 100 can be prevented by other means, such as by periodically or continuously monitoring, e.g., measuring or determining the inductance of the variable inductor 100. The DC control current 110 can be reduced in response to determining that the inductance of the variable inductor 100 is below a set value.

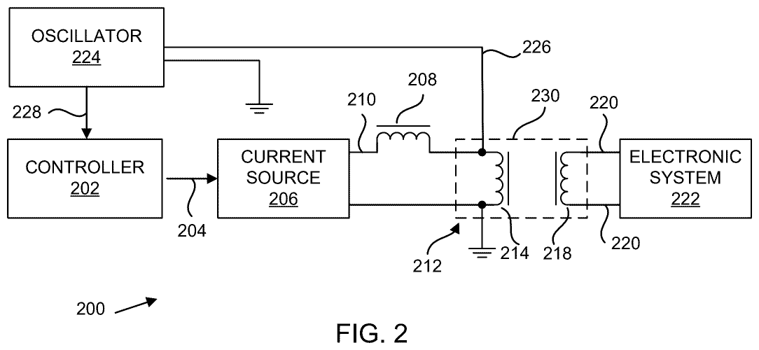

FIG. 2 depicts a block diagram of a control system 200 for a variable inductor 212 according to some examples. In some examples, the control system 200 may be used for the variable inductor 100 of FIG. 1. The variable inductor 212 may have features similar to, or the same as, the variable inductor 100 of FIG. 1. Variable inductor 212 includes magnetic core 230, control coil 214 and compensation coil 218. The control system 200 may include a DC current source 206 electrically coupled to a control coil 214 and configured to provide a DC control current 210 to the control coil 214, a controller 202 (e.g., a microcontroller unit (MCU) and/or a system on a chip (SOA)) operatively coupled to the current source 206 and configured to provide a control signal 204 (e.g., a control voltage) to the current source 206, an oscillator 224 coupled between the control coil 214 and the controller 202 and configured to sense (e.g., measure) an oscillation frequency of the oscillator 224, and a compensation coil 218 inductively coupled to the control coil 214 and electrically coupled to an electronic system 222 via connections 220. In some examples, the control coil 214 and the compensation coil 218 may respectively correspond to the control coil 104 and the two compensation coils 106 and 108 of the variable inductor of FIG. 1. A controllably variable inductance LV may be formed between the two terminals 220. As discussed with respect to FIG. 1, magnetic core 230 may include a material whose relative permeability decreases as the control current 210 flowing through the control coil 214 increases.

The current source 206 may be configured to provide DC control current 210 (e.g., the control current 110 in FIG. 1) to the control coil 214 based on the control signal 204 that it receives from the controller 202. For example, the control current 210 may change in response to corresponding changes in the control signal 204. In some examples, the control system 200 may include a current sensor, not shown in FIG. 2, configured to sense (e.g., measure) the control current 210 flowing through the control coil 214. As discussed in more detail herein, the controller 202 may monitor the control current 210 and set parameters and/or adjust the control current 210 based on the measured control current 210. Control system 200 may be configured to limit control current 210 below a set maximum to maintain the inductance of variable inductor 212 above a set minimum inductance in order to maintain the permeability of magnetic core 230 above a set minimum permeability.

The electronic system 220 may depend on a set range of values of the variable inductance LV of variable inductor 212 for proper operation. In some examples, the electronic system 220 may be configured to provide feedback (e.g., via control signaling not shown in FIG. 2 or wireless signals transmitted via a wireless transceiver, such as a Bluetooth radio) to the controller 202 to thereby control, to some set extent, the variable inductance LV of variable inductor 212. For example, the controller 202 may be configured to increase or decrease the control current 210 (thereby decreasing or increasing, respectively, the inductance of the variable inductor 212) based on the feedback signals received from the electronic system 222.

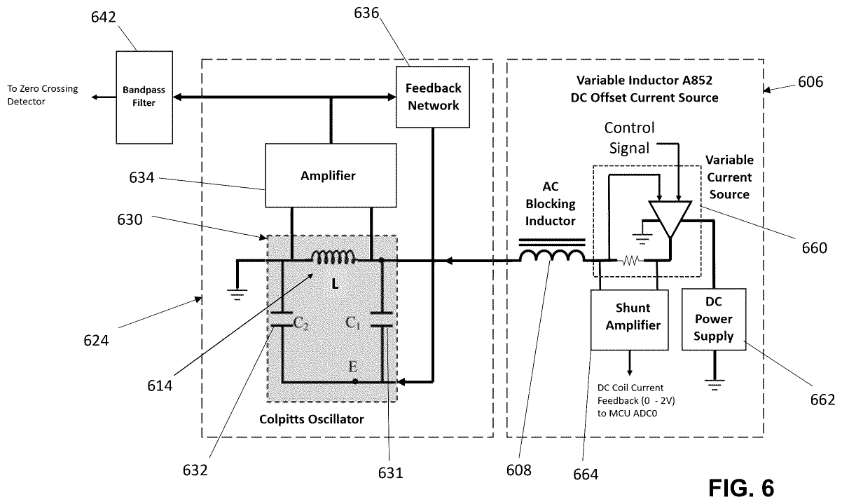

The oscillator 224 may be electrically connected to the control coil 214 via a connection 226 and configured to have a variable frequency of oscillation corresponding to variations in the inductance of control coil 214, which is proportional to the inductance of variable inductor 212. Thus, the control coil 214 may also function as a sensor coil. In some examples, the control coil 214 may form part of an LC or LCR resonant circuit in oscillator 224. The output 228 of oscillator 224 may be input to the controller 202, and the controller 202 may be configured to generate the control signal 204 based on the output frequency received from the oscillator 224. For example, based on the oscillation frequency of the oscillator 224, the controller 202 may be configured to determine (e.g., calculate) an inductance of the variable inductor 212. Thus, the control system 200 may be configured to monitor and controllably adjust the inductance of the variable inductor 212. Additional details of the oscillator 224, according to some examples, will be discussed below with reference to FIG. 6.

In some examples, an inductor 208 (e.g., an AC blocking coil) is coupled in series between one terminal of the control coil 214 and the current source 206. The inductor 208 may substantially block the flow of AC current from the control coil 214 back into the DC current source 206, which could disrupt operation of the DC current source 206.

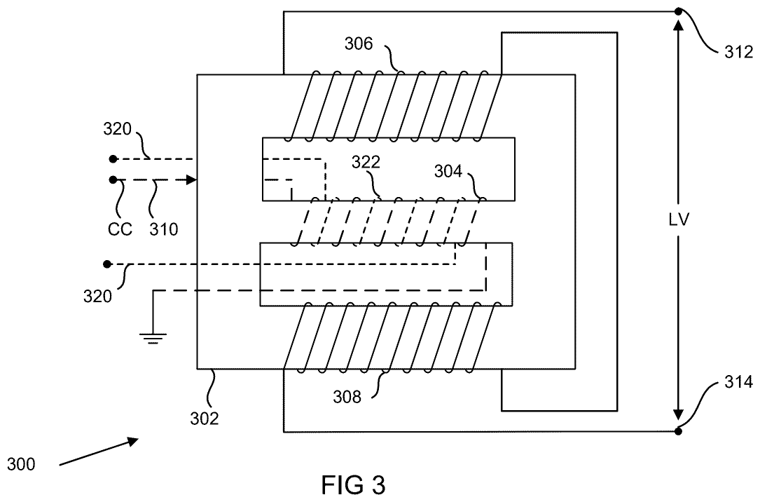

FIG. 3 depicts an example variable inductor 300 with a separate sensor coil 322 according to some examples. The variable inductor 300 may have some features similar to, or the same as, the features of the variable inductor 100 of FIG. 1, and redundant descriptions may not be repeated.

The variable inductor 300 may include a three-legged core 302 having a center leg and two outer legs. The three-legged core 302 may generally form the shape of the number 8. The variable inductor 300 may include a control coil 304, wound around the center leg of the core 302, and two compensation coils 306 and 308 that are respectively wound around the two outer legs of the core 302. The control coil 304 may be configured to receive a DC control current 310. The two compensation coils 306 and 308 may be connected in series or in parallel as part of the variable inductor 300 with a variable inductance LV. The two compensation coils 306 and 308 may be coupled between two terminals 312 and 314, which may be connecting points for other circuits or systems to connect to the variable inductor 300. The inductance LV of variable inductor 300 and the permeability of the material of the core 302 can be controllably adjusted based on the amplitude of the control current 310 provided to the control coil 304.

The sensor coil 322 may be wound around the center leg of the core 302 and connected to other systems via connections 320 for at least the purpose of sensing (e.g., measuring) an inductance of the variable inductor 300. The sensor coil 322 may be electrically insulated from the control coil 304 and, in some examples, may be wrapped around the control coil 304.

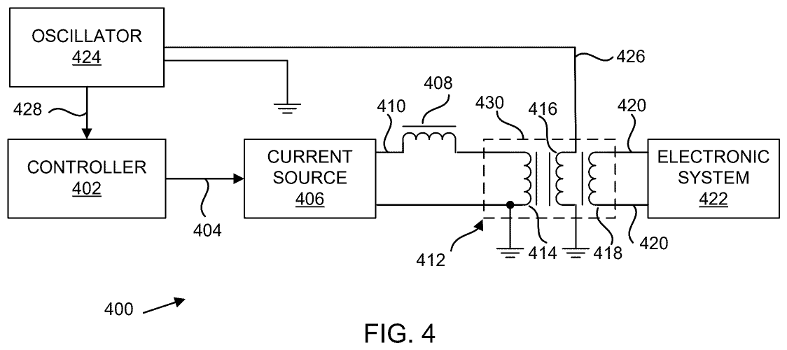

FIG. 4 depicts a block diagram for an example control system 400 of a variable inductor 412 according to some examples. The control system 400 may have features similar to, or the same as, the features of the control system 200 of FIG. 2, and redundant descriptions may not be repeated. The control system 400 may primarily differ from the control system 200 of FIG. 2 in that the variable inductor 412 includes a sensor coil 416 that is separate from a control coil 414. In some examples, the variable inductor 412 may be the variable inductor 300 of FIG. 3. Variable inductor 412 includes magnetic core 430, control coil 414, sensing coil 416 and compensation coil 418.

The control system 400 may include a DC current source 406 configured to provide a DC control current 410 to the control coil 414, a current sensor, not shown in FIG. 4, configured to sense (e.g., measure) the control current 410, an AC blocking inductor 408 electrically coupled between the control coil 414 and the current source 406, a controller 402 configured to provide a control signal 404 (e.g., control voltage) to the current source 406, and an oscillator 424 coupled between the sensor coil 416 and the controller 402, and a compensation coil 418 inductively coupled to the control coil 414 (e.g., via a common magnetic core) and electrically coupled to an electronic system 422 via connections 420. A controllably variable inductance (LV) may be formed between the two terminals 420.

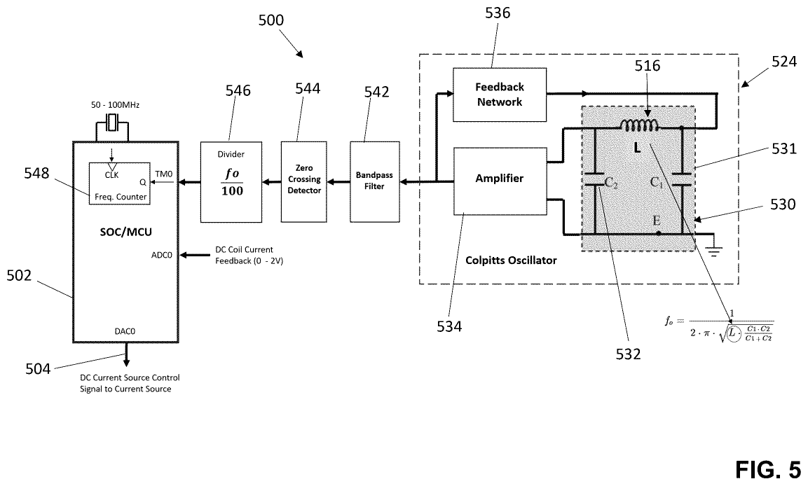

The oscillator 424 may be electrically coupled to the sensor coil 416 via a connection 426 and configured to sense (e.g., measure) an inductance of the variable inductor 412 based on the inductance of sensor coil 416, which is proportional to the inductance of variable inductor 412. In some examples, the sensor coil 416 may be a part of an LC or LCR resonant circuit in oscillator 424. The output 428 of oscillator 424 may be transmitted to the controller 402, and the controller 402 may be configured to generate the control signal 404 based on the output frequency of oscillator 424. Based on the oscillation frequency of the oscillator 424, the control system 400 can monitor and adjust the inductance of the variable inductor 412. Additional details of the oscillator 424, according to some examples, will be discussed below with reference to FIG. 5.

FIG. 5 is a schematic diagram of part of a control system 500 for a variable inductor according to some examples. In some examples, the control system 500 may form part of the control system 400 of FIG. 4. For example, the control system 500 may include a sensor coil 516, an oscillator 524 (e.g., a Colpitts oscillator) including the sensor coil 516, and a controller 502, and the sensor coil 516, oscillator 524, and controller 502 may respectively correspond to the sensor coil 416, oscillator 424, and controller 402 of the control system 400 of FIG. 4 in some examples.

The sensor coil 516 may be wound around a core (e.g., the center leg of the three-legged core 302 of FIG. 3), and the oscillator 524 may oscillate at a frequency corresponding to the inductance of the sensor coil 516, which is proportional to the inductance of the variable inductor, not shown in FIG. 5. The controller 502, may be configured to calculate the inductance of the variable inductor based on the oscillation frequency of oscillator 524. Additional details regarding this process are provided below.

The oscillator 524 may include an LC resonant circuit 530, an amplifier 534 coupled to the LC resonant circuit 530, and a feedback network 536 coupled to the LC resonant circuit 530.

The amplifier 534 may be configured to amplify the signal flowing through the LC resonant circuit 530. The output signal of the amplifier 534 may be routed to the controller 502 via one or more intermediate components including, for example, a bandpass filter 542, a zero crossing detector 544, and a divider 546. The output signal of the amplifier 534 may be routed to the feedback network 536. The LC resonant circuit 530 can oscillate in a stable manner at the oscillation frequency.

The LC resonant circuit 530 may include the sensor coil 516 and first and second capacitors 531 and 532. Current may oscillate through the LC resonant circuit 530 at an oscillation frequency f₀, which is the resonant frequency of the LC resonant circuit 530 and has a value that depends on first and second capacitances C1 and C2 of the first and second capacitors 531 and 532 and also on the inductance L of the sensor coil 516. In this example, the oscillation frequency f₀ may be defined by Equation 1 below, which can be rewritten to define the inductance L of the sensor coil 516 according to Equation 2 below.

$${f}_{0} = \frac{1}{2 π \sqrt{L \frac{{C}_{1} {C}_{2}}{{C}_{1} + {C}_{2}}}} \qquad [ Equation 1 ]$$

$$L = \frac{{C}_{1} + {C}_{2}}{4 {π}^{2} {f}_{0}^{2} {C}_{1} {C}_{2}} \qquad [ Equation 2 ]$$

As shown in Equation 2, the inductance L can be calculated based on the first and second capacitances C1 and C2, which are fixed quantities, and the oscillation frequency f₀. Because the first and second capacitances C1 and C2 may be known, the inductance L can be calculated if the oscillation frequency f₀ is also known, which can be determined based on the output of the amplifier 534 sent to the controller 502. The output of amplifier 534 may have an oscillation frequency f₀ and, thus, inductance L can be determined.

The output of amplifier 534 may be transmitted first to a bandpass filter 542. As discussed above, the inductive coupling system may include the variable inductor, a primary coil (e.g., of a wireless power transfer device), and a receiver coil (e.g., of an implantable medical device). The primary coil may be driven with an AC current at the operating power transfer frequency f(t). This can cause an alternating magnetic field to permeate through the core that the sensor coil 516 is wound around and, thus, cause a second current having the operating frequency f(t) to be superimposed on the current oscillating within the LC resonant circuit 530 at the oscillation frequency f₀. This second current may obscure the measurement of the oscillation frequency f₀, and the bandpass filter 542 can be used to filter out this second frequency f(t) to thereby improve the measurement of the oscillation frequency f₀.

In some examples, the LC resonant circuit 530 may be configured such that the oscillation frequency f₀ is significantly larger than (e.g., at least 5, 10, 15, or 20 times larger than) or smaller than (e.g., at least 5, 10, 15, or 20 times smaller than) the operating frequency f(t) (and/or resonant frequency) of the inductive coupling system. This will reduce the extent to which the second current interferes with the LC resonant circuit 530 and the measurement of the oscillation frequency f₀.

The output of the bandpass filter 542 may be input to the zero crossing detector 544 (e.g., a comparator), which may be configured to output a first pulse train signal (e.g., a digital pulse train, etc.) based on the filtered output that it received from the bandpass filter 542. The output of the bandpass filter 542 may have oscillation frequency f₀. The oscillation frequency f₀ may be measured by counting, e.g., via a frequency counter 548.

The output of the zero crossing detector 544 may be input to the divider 546, which may be configured to divide the frequency of the first pulse train signal (e.g., by a factor of 10, 100, 1000, etc.) and output a reduced frequency signal.

The output of divider 546 may be input to a frequency counter 548 of the controller 502, which may be configured to measure a frequency of the output of the divider 546. The controller 502 (e.g., the frequency counter 548) may then obtain the oscillation frequency f₀ by multiplying the measured output frequency of the divider 546 by the factor by which the divider 546 divided the output of the zero crossing detector 544. Thus, the oscillation frequency f₀ of the oscillator 524 may be accurately measured.

In response to measuring the oscillation frequency f₀, the controller 502 may be configured to determine (e.g., calculate) the inductance L of the core that the sensor coil 516 is wound around, for example, based on the measured oscillation frequency f₀, the known values of the first and second capacitances C1 and C2, and Equation 2 above. The controller 502 may then be configured to determine, based on the inductance L, whether to adjust the inductance L and, if so, how to adjust the control signal 504 transmitted to a DC current source (e.g., the current source 406 of FIG. 4) for adjusting the inductance L as described herein.

In some examples, the controller 502 may be configured to determine whether certain threshold conditions are satisfied and, in response to determining that such threshold conditions are satisfied, to maintain or decrease the control current (provided by the current source) by maintaining or decreasing the control signal 504 provided to the current source. As explained herein, this should reduce the magnetization of the core and cause the inductance L of the core to increase (or at least to not increase). The controller 502 may continue to monitor the oscillation frequency f₀ and adjust the inductance L, via the control signal 504, to avoid the threshold conditions.

The threshold conditions may be set (e.g., selected) to reduce the likelihood that the material properties of the core will be permanently altered by, for example, influences such as AC magnetic flux, DC magnetic flux, temperature, physical shock (e.g., physical impacts), and/or other influences (e.g., environmental influences) that may affect the magnetization and inductances of the core. For example, as explained above, it may be desirable to operate the variable inductor such that the core does not enter into the nonlinear range, at which point the core may experience whapping and be permanently degraded. In some examples, the threshold conditions may include the inductance L being at or below a lower inductance threshold and/or the control current being at or above an upper threshold. In some examples, the threshold conditions may include a change in the slope of the inductance L (e.g., with respect to the control current) being at or above a linearity error value (e.g., a percentage set within a range of less than 15%, such as between 5% and 10%). The slope of the inductance L may refer to a rate of change of the inductance with respect to a corresponding change in the control current and may be based on a ratio of a change in inductance to a corresponding change in the control current.

As explained herein, the control current initially causes a linear change in the inductance L of the core, and the inductance L can be controllably set within this linear range without permanently altering the core's material properties. However, as the control current continues to increase beyond this linear range, the core's inductance L exhibits a non-linear change with respect to the control current, and the material properties of the core will begin to permanently change. It can therefore be desirable to maintain the core's inductance L within the linear range and to avoid the non-linear range. The slope of the core's inductance may be directly measured for this purpose, as explained in more detail herein, or the lower inductance threshold and/or upper control current threshold may be determined and used as a proxy for determining when the core's inductance L is too close to the non-linear range.

For example, the control current may be gradually increased (e.g., in a step-wise manner), and the inductance may each be monitored as the control current is increased. The slope of the inductance (e.g., with respect to the control current) and changes in the slope of the inductance may also be calculated (e.g., by the controller 502) based on the measured inductances. When the change in the slope of the inductance is determined to exceed the linearity error value, an associated inductance and control current may also be determined and used as a basis for determining the lower inductance threshold value and/or the upper control current threshold. As the controller 502 continues to monitor and control the inductance L of the core, it can adjust the control signal 504 to controllably set the control current to be below the upper control current threshold and/or to set the inductance to be above the lower inductance threshold.

FIG. 6 is a schematic diagram of part of a control system 600 for a variable inductor according to some examples. In some examples, the control system 600 may form part of the control system 200 of FIG. 2. For example, the control system 600 may include a control coil 614, an oscillator 624 (e.g., a Colpitts oscillator) including the control coil 614, an AC blocking inductor 610, and a current source 606, and the control coil 614, oscillator 624, AC blocking inductor 608, and current source 606 may respectively correspond to the control coil 216, oscillator 224, inductor 208, and current source 206 of the control system 200 of FIG. 2 in some examples. The control system 600 may include some features similar to, or the same as, features of the control system 500 of FIG. 5, and redundant descriptions may not be repeated.

The control coil 614 may be wrapped around a core (e.g., the center leg of the three-legged core 102 of FIG. 1) and be configured to both adjust and sense (e.g., measure) the inductance L of the control coil 614. The oscillator 624 may include an LC resonant circuit 630, including the control coil 614 and first and second capacitors 631 and 632, an amplifier 634, and a feedback network 636. Current may oscillate through the LC resonant circuit 630 at an oscillation frequency f₀ of the oscillator 624 (e.g., at a resonant frequency of the LC resonant circuit 630). The amplifier 634 may be configured to amplify the current flowing through the LC resonant circuit 630. The output of amplifier 634 may be input to a controller (e.g., the controller 202) via one or more intermediate components, including a bandpass filter 642, a zero crossing detector (not shown), and/or a divider (not shown). The output of amplifier 634 may be fed back into the LC resonant circuit 630 via the feedback network 636.

The current source 606 may be configured to controllably provide a DC current to the LC resonant circuit 630 through the AC blocking inductor 608. The current source 606 may include a variable current source 660, a DC power supply 662, and a shunt amplifier 664. The DC power supply 662 may be configured to provide a voltage to the variable current source 660. The variable current source 660 may be configured to receive control signal 204 from the controller and to generate a DC current using the voltage received from the DC power supply 662. Variable current source 660 may be configured to output the generated DC current across a shunt resistor of the shunt amplifier 664 and to the AC blocking inductor 608. The shunt amplifier 664 may be configured to measure a voltage drop across the shunt resistor and to provide information about the voltage drop to the controller. The controller may be configured to use this feedback information from the shunt amplifier 664 to, for example, determine the DC current provided to the control coil 614 and/or to adjust the control signal.

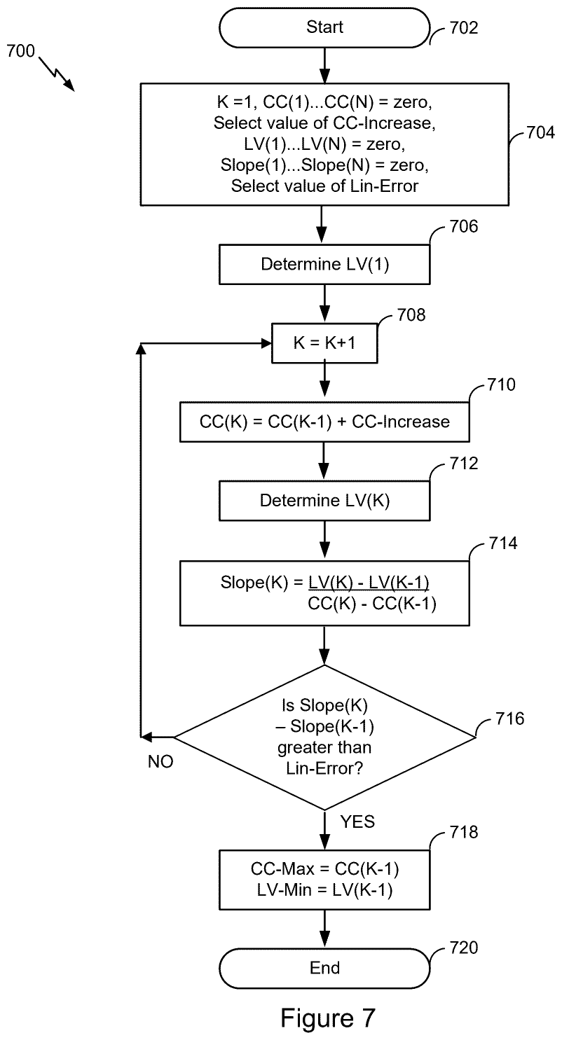

FIG. 7 depicts a flowchart for a method 700 of calibration for the safe operation of a variable inductor according to some examples. In some examples, the method 700 may be used to calibrate any of the variable inductors 100, 212, 300 and 412 of FIGS. 1-4. The method 700 may be implemented using a control system for the variable inductor, such as the control systems 200 and 400 of FIGS. 2 and 4. The method 700 may determine a maximum control current CC-Max (e.g., the upper threshold amplitude) and a minimum variable inductance LV-Min (e.g., the lower inductance threshold) for the safe operation of the variable inductor, to prevent permanent degradation of the material (e.g., ferrite) of the core of the variable inductor due to over magnetization of the ferrite core. The method 700 may be performed at the very start of operation of such a system, periodically, or in a continuous, repeated manner to actively monitor the operating conditions of the variable inductor, and to prevent damage to the ferrite core due to over magnetization.

The method 700 begins at a first operation 702 and proceeds to a second operation 704, where initial values of various variables are set. In the second operation 704, a counter K is set equal to 1. A plurality of N initial values of control current CC(1) . . . CC(N) are set to zero. A value of a current control increase CC-Increase is set. The control current increase CC-Increase may refer to an amount by which the control current CC is increased incrementally during the method 700. In some examples, the control current increase CC-Increase is a constant value. In some other examples, the control current increase CC-Increase may be a variable quantity. A plurality of N initial values of the variable inductance LV(1) . . . LV(N) are set to zero. A plurality of N initial values of the slope Slope(1) . . . Slope(N) of the inductance LV of the variable inductor versus the control current CC applied to the variable inductor is set to zero. The Slope(j) may refer to the value of a change in inductance LV (in response to a change in control current CC) divided by the corresponding change in the control current CC. The Slope(j) may correspond to the slope of a curve of the inductance LV mapped onto a Y-axis as a function of the control current CC mapped onto an X-axis as the control current CC is increased for N iterations. A value of a linearity error Lin-Error is set equal to a maximum allowable change in the slope of the inductance LV between iterations of increasing the control current CC by the control current increase CC-Increase. For example, the linearity error Lin-Error may be set to a percentage value (e.g., a percentage of the previous or current slope of the inductance LV as a function of the control current) between 0% and 15%, such as within a range of 5% to 15%.

As explained above, as the control current increases from zero amps, the correlation between the inductance of the core and the control current will initially be linear and then enter into the nonlinear range. Permanent changes to the material properties of the core will occur in the nonlinear range, and the linear error Lin-Error can be used to indicate when the core's inductance is in, or is approaching, the nonlinear range.

During a third operation 706, a first value of the variable inductance LV(1), associated with when a first control current CC(1) is applied, is calculated. In some examples, the control current CC(j) may be calculated in the manner described with reference to FIG. 5 or FIG. 6. As the control current CC(j) is increased incrementally by the control current increase CC-Increase, the associated inductance LV(j) of the variable inductor will typically decrease.

In a fourth operation 708, the value of the incremental counter K is increased by one. In a fifth operation 710, the control current CC is increased by the control current increase CC-Increase, such that CC(K)=CC(K−1)+CC-Increase. In a sixth operation 712, the inductance LV(K) of the variable inductor is determined by the control system.

In a seventh operation 714, the Slope(K) is computed and is equal to the ratio of the change in the variable inductance LV (in response to the change in control current CC) to the change in the control current CC between incremental increases of the control current CC. This may be computed via Equation 3 below:

$$Slope ( K ) = \frac{LV ( K ) - LV ( K - 1 )}{CC ( K ) - CC ( K - 1 )} \qquad Equation 3$$

In an eighth operation 716, a Slope Change value is determined and compared to the linearity error Lin-Error. The Slope Change may be determined based on two Slope values between incremental increases in the control current CC. For example, the Slope Change may be based on (e.g., be equal to) a difference between the two Slope values (e.g., Slope(K) minus Slope(K−1)). Comparing the Slope Change to the linearity error Lin-Error in this example may entail dividing the difference between the two Slope values by one of the two Slope values (e.g., by Slope(K−1)) and then multiplying by 100% to obtain a percentage. A percentage of 0% indicates that the two slopes are equal and that the inductance LV curve (as a function of the control current CC) is highly linear, while larger percentages indicate higher degrees of nonlinearity.

The Slope Change may be determined based on the two Slopes in a different manner in other examples, such as by the ratio of the two Slope values. In such an example, a ratio of 1 indicates a high degree of linearity and ratios deviating significantly from 1 indicate a high degree of nonlinearity. Similarly, the linearity error Lin-Error may be defined differently in other examples based on how the Slope Change is defined.

If the Slope Change exceeds the linearity error Lin-Error, then the method 700 proceeds to a ninth operation 718, where the maximum control current CC-Max is set equal to the previous value of the control current (e.g., CC(K−1)), which is associated with a Slope Change that did not exceed the linearity error Lin-Error. Similarly, the minimum variable inductance LV-Min may be set equal to the previous value of the variable inductance LV(K−1). More generally, the maximum control current CC-Max and the minimum variable inductance LV-Min may be set based on the control current CC(K) and the inductance LV(K) associated with the Slope Change that exceeded the linearity error Lin-Error.

However, if, during the eighth operation 716, it is determined that the Slope Change does not exceed the linearity error Lin-Error, then the method 700 may return to the fourth operation 708 and incrementally increase the value of K again. Accordingly, the fourth to eighth operations 708 to 716 can form at least part of a logic loop that incrementally increases the control current until a control current CC (and associated inductance LV) are determined that cause the Slope Change to exceed the linearity error Lin-Error, at which point it may be determined that the core is within, or is approaching, the non-linearity range where permanent changes to the magnetic properties of the core may occur. The method 700 ends at a tenth operation 720.

The control system (e.g., the control system of FIG. 2 or of FIG. 4) may be configured to control the variable inductor (e.g., control the inductance of the variable inductance by controlling the control current provided to a control coil) based on the values of CC-Max and LV-Min, which may provide the control system parameters to prevent the over-magnetization and permanent degradation of the core of the variable inductor. For example, the control system may continue to monitor the inductance of the sensing coil, determine if the inductance has decreased below the minimum inductance LV-Min, and decrease the control current to cause the inductance to increase back above the minimum inductance LV-Min. This can ensure that the core does not drift into the nonlinear range. Similarly, the control system can increase the control current up to, but not beyond, the maximum control current CC-Max to ensure that the core does not drive into the non-linear range.

In some examples, the control system may periodically re-measure the Slope Change (e.g., via incrementally increasing or decreasing the control current at least three times, measuring the associated at least three inductances, and calculating the Slope Change) and determine whether, and by how much, to adjust the control current based on the newly measured Slope Change.

In some examples, the control system may periodically re-measure the Slope Change for purposes of re-calculating the minimum inductance LV-Min and/or the maximum control current CC-Max. This can be beneficial because, as discussed above, the properties of the core are susceptible to unintentional changes over time. This can shift the nonlinear range of the core's properties, making it desirable to redetermine the minimum inductance LV-Min and/or the maximum control current CC-Max, which can help to protect the core from further permanent changes during subsequent operations.

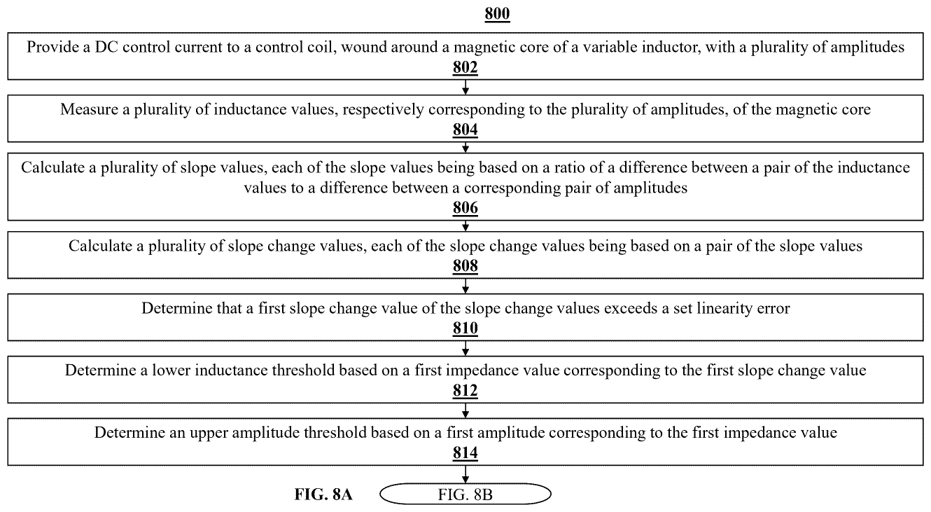

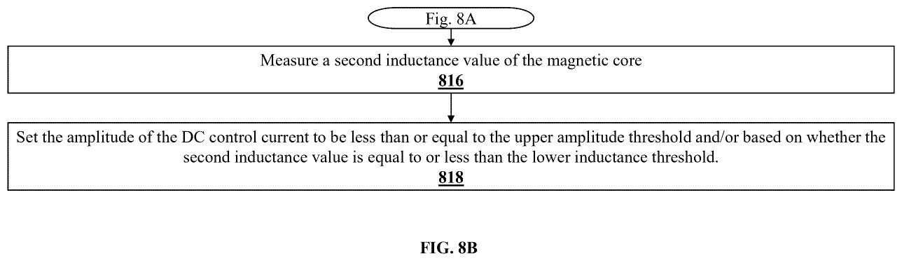

FIG. 8 is a flowchart of another method 800 for operating a variable inductor according to some examples. The method 800 may be practiced, for example, by any of the control systems described herein.

The method 800 may include a first operation 802 of providing a DC control current to a control coil, wound around a magnetic core of a variable inductor, with a plurality of amplitudes, and a second operation 804 of measuring a plurality of inductance values, respectively corresponding to the plurality of amplitudes, of the magnetic core. For example, the DC control current may be provided with a plurality of incrementally increasing amplitudes to the control coil 214 or 414, and a corresponding inductance may be measured for each amplitude.

The method 800 may include a third operation 806 of calculating a plurality of slope values, and each of the slope values may be based on a ratio of a difference between a pair of the inductance values to a difference between a corresponding pair of amplitudes. In some examples, the pair of inductance values may be adjacent in time (e.g., one inductance value was obtained after the other inductance value was obtained) or adjacent in value (e.g., no inductance value from among the plurality of measured inductance values is between the two inductance values).

The method 800 may include a fourth operation 808 of calculating a plurality of slope change values, and each of the slope change values may be based on a pair of the measured slope values. The slope change value may be calculated, for example, based on a difference between the pair of slope values, based on a ratio of the pair of slope values, or in some other manner that characterizes a degree by which the two slope values differ from each other.

The method 800 may include a fifth operation 810 of determining that a first slope change value of the slope change values exceeds a set linearity error. This may entail comparing each of the slope change values to the set linearity error. As discussed herein, the linearity error may indicate that an inductance associated with the slope change value is in, or is approaching, the nonlinear range of inductance values.

The method 800 may include a sixth operation 812 of determining a lower inductance threshold based on a first inductance associated with the first slope change value, and a seventh operation 814 of determining an upper amplitude threshold based on a first amplitude corresponding to the first inductance. In some examples, the lower inductance threshold and the upper amplitude threshold may be respectively set equal to the first inductance (or another inductance value from among the plurality of measured inductance values, such as a higher inductance value) and to the first amplitude (or another amplitude from among the plurality of measured amplitudes, such as a lower amplitude).

During an eighth operation 816 (e.g., after the sixth and seventh operations 812 and 814), a second inductance value of the magnetic core may be measured. The eighth operation 816 may represent continued monitoring by a control system of the magnetic core's inductance after the lower inductance threshold and the upper amplitude have been set.

During a ninth operation 818, the control system may set the amplitude of the DC control current to be less than or equal to the upper amplitude threshold and/or based on whether the second inductance value is equal to or less than the lower inductance threshold. For example, the control system may increase the amplitude if it is determined that the amplitude is still less than the upper amplitude threshold and/or if the second inductance value is still above the lower inductance threshold. Or the control system may decrease the amplitude if it is determined that the second inductance value is at or below the lower inductance threshold. As discussed herein, the control system may also be configured to adjust the control current based on feedback information received from an electronic system (e.g., a wireless power transfer device) that the variable inductor is coupled to. For example, the feedback information may indicate that a resonant frequency of the electronic system has deviated from an operating frequency of the electronic system, and the control system may adjust the control current to correct for this deviation.

Although some methods for controlling a variable inductor have been discussed with reference to FIGS. 7 and 8, the present disclosure is not limited thereto. Control systems for controlling variable inductors, and processes performed by such control systems, have been described herein, for example, with reference to FIGS. 1-6, and the present disclosure includes all methods for controlling a variable inductor that include any combination of such processes in any suitable order.

Features from an example, or from multiple examples, described in the present disclosure may be combined with each other, partially or entirely, and may be technically interlocked and operated in various ways, and the examples described herein may be implemented independently of each other or in conjunction with each other.

Although specific examples are described herein, the scope of the technology is not limited to those specific examples. Moreover, while different examples may be described separately, such examples and examples may be combined with one another in implementing the technology described herein. One skilled in the art will recognize other examples or improvements that are within the scope and spirit of the present technology. Therefore, the specific elements, features, and processes are disclosed only as example examples. The scope of the technology is defined by the following claims and any equivalents thereof.

What is claimed is:

1. A control system, comprising:
a variable inductor comprising a magnetic core, a first coil wound around the magnetic core, and a control coil wound around the magnetic core; and
a sensor coil wound around the magnetic core,
wherein the first coil wound around the magnetic core is coupled between first and second terminals and has a variable inductance across the first and second terminals.

2. The control system of claim 1, further comprising:
an oscillator coupled to the sensor coil; and
a controller coupled to the oscillator and configured to determine, based on an oscillation frequency of the oscillator, an inductance of the variable inductor.

3. The control system of claim 2, further comprising an electronic system coupled to the first and second terminals of the variable inductor,
wherein a resonant frequency of the electronic system depends on the inductance of the variable inductor and is either:
less than twenty percent of the oscillation frequency of the oscillator; or
more than five times higher than the oscillation frequency of the oscillator.

4. The control system of claim 2, further comprising a current source configured to provide a DC control current to the control coil to control the inductance of the variable inductor.

5. The control system of claim 4, wherein the controller is coupled to the current source and is configured to determine a maximum DC control current corresponding to a set minimum inductance of the variable inductor.

6. The control system of claim 4, wherein the controller is configured to determine a slope equal to a ratio of a change in the inductance of the variable inductor relative to a corresponding change in the DC control current provided to the control coil.

7. The control system of claim 6, wherein the controller is configured to maintain a change in the slope below a set linearity error.

8. The control system of claim 7, wherein the set linearity error is selected from any percentage between 0.0 and ±15.0.

9. The control system of claim 4, wherein the controller is configured to maintain a rate of change in the DC control current provided to the control coil below a set maximum.

10. The control system of claim 4, wherein the controller is configured to maintain the DC control current provided to the control coil below a set maximum DC control current.

11. The control system of claim 1, wherein the sensor coil comprises the control coil wound around the magnetic core.

12. The control system of claim 1, further comprising a current sensor configured to measure a DC current provided to the control coil.

13. The control system of claim 1, wherein the magnetic core is a three legged core comprising two outer legs and a middle leg between the two outer legs,
wherein the control coil is wound around the middle leg,
wherein the first coil comprises two sub-coils respectively wound around the two outer legs, and
wherein the magnetic core comprises at least one of a ferrite, a perminvar ferrite, a nickel zinc ferrite, Fair-Rite 61 ferrite, or Fair-Rite 67 ferrite.

14. The control system of claim 13, wherein the sensor coil is wound around the middle leg of the three legged core.

15. The control system of claim 1, wherein the inductance of the variable inductor is proportional to a permeability of the magnetic core.

16. A method for controlling an inductance of a variable inductor, the variable inductor comprising a magnetic core, a first coil, a control coil, and a sensor coil, the first coil, control coil, and sensor coil each being wound around the magnetic core, and the first coil having a variable inductance across first and second terminals, the method comprising:
regulating the inductance of the variable inductor via a DC control current provided by a current source coupled to the control coil; and
monitoring an oscillation frequency of an oscillator coupled to the sensor coil.

17. The method of claim 16, further comprising:
determining the inductance of the variable inductor based on the oscillation frequency of the oscillator.

18. The method of claim 17, further comprising:
increasing the DC control current to the control coil by a set amount in a first increase;
determining the inductance of the variable inductor due to the first increase;
increasing the DC control current to the control coil by the set amount in a second increase;
determining the inductance of the variable inductor due to the second increase; and
determining a rate of change in the inductance of the variable inductor relative to the change in the DC control current.

19. The method of claim 18, further comprising:
repeatedly increasing the DC control current to the control coil if the rate of change in the inductance of the variable inductor relative to the change in the DC control current is less than or equal to a set linearity error;
maintaining, or decreasing, the DC control current to the control coil if the rate of change in the inductance of the variable inductor relative to the change in the DC control current is greater than the set linearity error; and
setting a maximum control current in the controller based on the last DC control current that corresponds to the rate of change in the inductance of the variable inductor relative to the change in the DC control current that is less than or equal to the set linearity error.

20. The method of claim 19, further comprising:
setting a minimum value of the inductance of the variable inductor in the controller based on the value of the inductance of the variable inductor corresponding to the maximum control current.

21. A control system, comprising:
a variable inductor configured to couple to an electronic system and comprising:
a magnetic core, and
a control coil wrapped around the magnetic core;
a current source configured to provide a DC control current to the control coil; and
an inductance sensor configured to measure an inductance of the variable inductor,
wherein the control system is configured to set an amplitude of the DC control current based on a measured inductance measured by the inductance sensor.

22. An inductance-variable system, comprising:
the control system of claim 21, the control system comprising a first coil wound around the magnetic core and electrically coupled between two terminals; and
an electronic system coupled to the variable inductor via the two terminals and having a resonant frequency dependent on the inductance of the variable inductor,
wherein the control system is configured to set the amplitude of the DC control current further based on the resonant frequency of the electronic system.

23. The inductance-variable system of claim 22, wherein the electronic system comprises a wireless power transfer device comprising primary coil configured to inductively transmit power.

24. The inductance-variable system of claim 23, wherein the electronic system further comprises an implantable medical device comprising a secondary coil configured to inductively receive power from the primary coil.

25. The control system of claim 21, wherein the magnetic core comprises two outer legs and an intermediate leg, and the control coil is wound around the center leg.

26. The control system of claim 21, wherein the inductance sensor comprises a resonant circuit comprising a sensor coil wound around the magnetic core.

27. The control system of claim 26, wherein the control system is configured to measure an oscillation frequency of the resonant circuit and to calculate the inductance of the variable inductor based on the measured oscillation frequency.

28. The control system of claim 26, wherein the sensor coil and the control coil are the same coil.

29. The control system of claim 26, wherein the sensor coil is separate from, and electrically insulated from, the control coil.

30. The control system of claim 26, further comprising an AC blocking coil electrically coupled between the current source and the sensor coil.

31. The control system of claim 21, wherein the control system is configured to:
provide the DC control current with a plurality of amplitudes;
measure a plurality of inductance values, respectively corresponding to the plurality of amplitudes, of the variable inductor; and
determine, based on the inductance values and the amplitudes, at least one of a lower inductance threshold or an upper amplitude threshold.

32. The control system of claim 31, wherein the control system is configured to:
calculate a plurality of slope values, each of the slope values being based on a ratio of a difference between a pair of the inductance values to a difference between a corresponding pair of amplitudes;
calculate a plurality of slope change values, each of the slope change values being based on a pair of the slope values;
determine that a first slope change value of the slope change values exceeds a set linearity error; and
determine the at least one of the lower inductance threshold or the upper amplitude threshold based on first impedance value and/or a first amplitude, the first impedance value being corresponding to the first slope change value and the first amplitude corresponding to the first impedance value.

33. The control system of claim 21, wherein the control system is configured to set the amplitude of the DC control current based on whether the inductance of the variable inductor is at or below a lower inductance threshold.

34. The control system of claim 21, wherein the control system is configured to set the amplitude of the DC control current within a range less than an upper amplitude threshold.

35. The control system of claim 21, wherein the control system is configured to set the amplitude of the DC control current based on a rate of change of the inductance of the magnetic core, with respect to a corresponding change of the amplitude of the DC control current.
